(19) United States
(12) Patent Application Publication
(10) Pub. No.: US 2026/0348047 A1
(43) Pub. Date: Nov. 5, 2026

(54) GROUP-III NITRIDE CRYSTAL AND PRODUCTION METHOD THEREFOR

(71) Applicant: PANASONIC HOLDINGS CORPORATION, Osaka (JP)

(72) Inventors: Junichi TAKINO, Osaka (JP); Shunichi MATSUNO, Kyoto (JP)

(21) Appl. No.: 19/544,238

(22) Filed: Feb. 19, 2026

Related U.S. Application Data
(63) Continuation of application No. PCT/JP2024/005990, filed on Feb. 20, 2024.

(30) Foreign Application Priority Data
Aug. 21, 2023 (JP) 2023-134103

(51) Int. Cl. C30B 25/16; C30B 29/40

(52) U.S. Cl. CPC C30B 25/165; C30B 29/403

(57) ABSTRACT

A Group-III nitride crystal, includes: a base portion made of Group-III nitride crystal, having a growth surface with a recessed growth pit; and a filling portion made of Group-III nitride crystal filling in the recessed growth pit on the growth surface.

### CROSS REFERENCE TO RELATED APPLICATION

This application claims priorities of Japanese Patent Application No. 2023-134103 filed on Aug. 21, 2023 and PCT Application No. PCT/JP2024/005990 filed on Feb. 20, 2024, the contents of which are incorporated herein by reference.

### BACKGROUND OF THE INVENTION

### 1. Field of the Invention

The present disclosure relates to a Group-III nitride crystal and a method for producing the same.

### 2. Description of the Related Art

Vertical GaN power devices require a GaN substrate with low resistivity and low dislocation density. For example, in the case of fabricating an n-type low resistivity GaN substrate, pits have been formed during growth to improve carrier concentration and reduce dislocation density (see, e.g., JP2021-50107A).

However, the production method described in JP2021-50107A suffers from the problem that breakage and cracks occur when the temperature is lowered after growth, resulting in a low production yield of the Group-III nitride crystal. The occurrence of breakage and cracks is due to the facts that the growth surface is covered with pits (growth pits) and that there is a difference in the thermal expansion coefficient between the seed substrate and the growth layer.

FIG. 1A is a schematic cross-sectional view showing the vertical cross-sectional structure at high temperature immediately after GaN crystal growth on a seed substrate by the oxide vapor phase epitaxy (OVPE) method, and FIG. 1B is a schematic cross-sectional view showing the vertical cross-sectional structure after cooling to room temperature subsequent to FIG. 1A. When low-resistivity n-type GaN is fabricated by adding oxygen at a higher concentration than that of the seed substrate using the OVPE method described in JP2021-50107A, the thermal expansion coefficient of the n-type low-resistivity GaN is greater than that of the seed substrate. In this case, as shown in FIG. 1B, the growth layer shrinks more than the seed substrate during cooling after growth, resulting in deformation into a downward convex shape. Furthermore, if pits are present on the surface, the stress generated on the surface is greater than that in a flat case, as indicated by the arrows in FIG. 1B. Therefore, the probability of breakage and cracks occurring increases.

### SUMMARY

The present disclosure is intended to solve the above-mentioned problems, and one non-limiting and exemplary embodiments provides a Group-III nitride crystal and a method for producing a Group-III nitride crystal that can improve the production yield when producing the Group-III nitride crystal.

In one general aspect, the techniques disclosed here feature: a Group-III nitride crystal, comprising:
a base portion made of Group-III nitride crystal, having a growth surface with a recessed growth pit; and
a filling portion made of Group-III nitride crystal filling in the recessed growth pit on the growth surface.

In another general aspect, the techniques disclosed here feature: a method for producing a Group-III nitride crystal, comprising:
preparing a seed substrate;
growing a Group-III nitride crystal three-dimensionally on the seed substrate by supplying a Group III element oxide gas and a nitrogen-containing gas onto the seed substrate so as to form a base portion made of the Group-III nitride crystal on the seed substrate, the base portion having a growth surface with a recessed growth pit; and
smoothing the growth surface of the base portion made of the Group-III nitride crystal by two-dimensionally growing a Group-III nitride crystal as a filling portion to fill in the recessed growth pits on the growth surface.

According to the Group-III nitride crystal and the method for producing the same according to the present disclosure, the production yield in producing Group-III nitride crystal can be improved, and high-quality Group-III nitride crystal can be produced.

Additional benefits and advantages of the disclosed embodiments will be apparent from the specification and figures. The benefits and/or advantages may be individually provided by the various embodiments and features of the specification and drawings disclosure, and need not all be provided in order to obtain one or more of the same.

### BRIEF DESCRIPTION OF DRAWINGS

The present disclosure will become readily understood from the following description of non-limiting and exemplary embodiments thereof made with reference to the accompanying drawings, in which like parts are designated by like reference numeral and in which:

FIG. 1A is a schematic cross-sectional view showing the vertical cross-sectional structure at high temperature immediately after GaN crystal growth on a seed substrate by the OVPE method;

FIG. 1B is a schematic cross-sectional view showing the vertical cross-sectional structure after cooling to room temperature subsequent to FIG. 1A;

FIG. 2A is a schematic cross-sectional view showing the vertical cross-sectional structure at high temperature immediately after GaN crystal growth on the seed substrate by the OVPE method;

FIG. 2B is a schematic cross-sectional view showing the cross-sectional structure of a vertical plane of a Group-III nitride crystal substrate in which a smoothing step has been carried out after FIG. 2A to form a filling portion where recessed growth pits are filled in the growth surface, in a production method for a Group-III nitride crystal substrate according to a first embodiment;

FIG. 3A is a chronological flowchart of the method for producing a Group-III nitride crystal substrate according to the first embodiment;

FIG. 3B shows, as steps, functional units from upstream to downstream within a production apparatus used in this production method;

FIG. 4 is a schematic cross-sectional view of the apparatus for producing a Group-III nitride crystal substrate according to the first embodiment; and

FIG. 5 is a diagram showing the relationship between the oxygen density and the stress generated in the filling portion in the smoothing step.

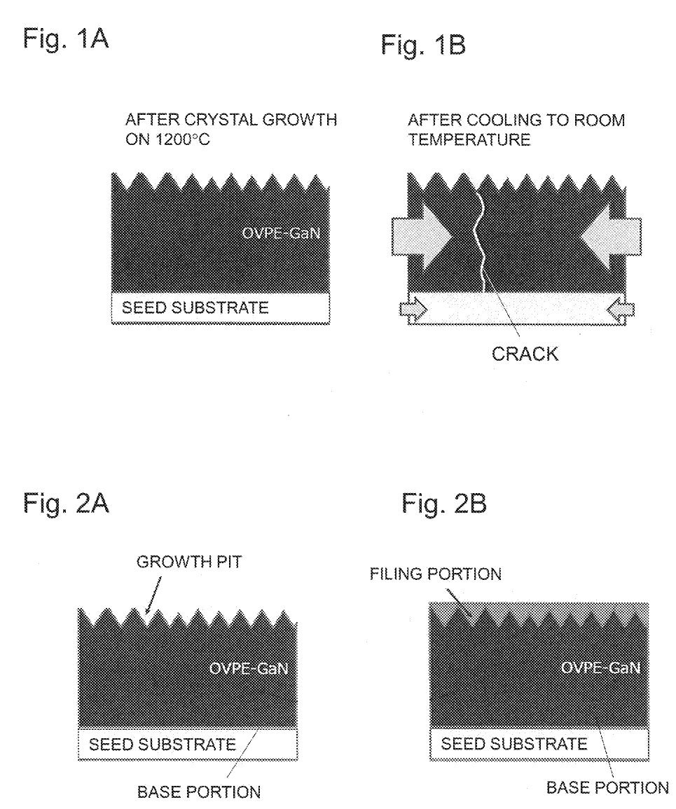

### DETAILED DESCRIPTION

A Group-III nitride crystal according to a first aspect, includes:
a base portion made of Group-III nitride crystal, having a growth surface with a recessed growth pit; and
a filling portion made of Group-III nitride crystal filling in the recessed growth pit on the growth surface.

The Group-III nitride crystal according to a second aspect in addition to the first aspect, the growth pit is filled with a Group-III nitride crystal, and
the base portion has an oxygen density of 1×10²⁰ atoms/cm³ or more.

The Group-III nitride crystal according to a third aspect in addition to the first or second aspect, the growth pit is filled with a Group-III nitride crystal,
the base portion has an oxygen density of 1×10²¹ atoms/cm³ or more, and
the filling portion has an oxygen density of 4.8×10²⁰ atoms/cm³ or more.

The Group-III nitride crystal according to a fourth aspect in addition to any one of the first to third aspects, the growth pit is filled with a Group-III nitride crystal, and the dislocation density is 5×105cm−2 or less.

A method for producing a Group-III nitride crystal according to a fifth aspect, includes:
preparing a seed substrate;
growing a Group-III nitride crystal three-dimensionally on the seed substrate by supplying a Group III element oxide gas and a nitrogen-containing gas onto the seed substrate so as to form a base portion made of the Group-III nitride crystal on the seed substrate, the base portion having a growth surface with a recessed growth pit; and
smoothing the growth surface of the base portion made of the Group-III nitride crystal by two-dimensionally growing a Group-III nitride crystal as a filling portion to fill in the recessed growth pits on the growth surface.

The method for producing a Group-III nitride crystal according to a sixth aspect in addition to the fifth aspect, smoothing the growth surface includes controlling the amounts of the Group III element oxide gas and the nitrogen-containing gas to be supplied to set the V/III ratio to 5 or greater.

The method for producing a Group-III nitride crystal according to a seventh aspect in addition to the fifth or sixth aspect, smoothing the growth surface includes increasing the temperature of the seed substrate by 50°C or more from that in the step of growing the Group-III nitride crystal.

The method for producing a Group-III nitride crystal according to an eighth aspect in addition to any one of the fifth to seventh aspects, in the course of smoothing the growth surface of the Group-III nitride crystal, the oxygen density in a region where the recessed growth pits have been filled in is 4.8×10²⁰ atoms/cm³ or more.

Group-III nitrides crystal and methods for producing the same according to embodiments will be described in detail below with reference to the accompanying drawings. Note that the present disclosure is not limited to these embodiments.

### First Embodiment

### Group-III Nitride Crystal

FIG. 2A is a schematic cross-sectional view showing the vertical cross-sectional structure at high temperature immediately after GaN crystal growth on the seed substrate by the OVPE method, and FIG. 2B is a schematic cross-sectional view showing the cross-sectional structure of a vertical plane of a Group-III nitride crystal substrate in which a smoothing step has been carried out after FIG. 2A to form a filling portion where recessed growth pits are filled in the growth surface, in a production method for a Group-III nitride crystal substrate according to a first embodiment.

An overview of the Group-III nitride crystal according to the first embodiment will be described with reference to FIGS. 2A and 2B. The Group-III nitride crystal according to the first embodiment is a Group-III nitride crystal grown on a seed substrate. This Group-III nitride crystal has a base portion made of Group-III nitride crystal grown on the seed substrate and the base portion having a growth surface with recessed growth pits, and a filling portion made of Group-III nitride crystal filling in the recessed growth pits on the growth surface.

Methods of filling the growth pits require switching growth mode of the Group-III nitride crystal to two-dimensional growth. Examples of the methods for switching from the three-dimensional growth mode used in normal crystal growth to the two-dimensional growth mode include increasing the growth temperature compared to the growth of the base portion shown in FIG. 2B or increasing the V/III ratio (the ratio of the Group V source to the Group III source). Examples of means for increasing the V/III ratio include increasing the supply amount of the Group V source or decreasing the supply amount of the Group III source. By controlling the growth conditions for the filling portion, it is possible to control the oxygen density of the filling portion and thereby control the difference in thermal expansion coefficient from the base portion.

The first effect of forming the filling portion is that it can reduce stress concentration when a load is applied to the base portion by smoothing the surface irregularities formed by growth pits. For example, when a Group-III nitride crystal is grown on a seed substrate while rotating during the growth process, contact with the substrate susceptor is unavoidable, and a load is applied from the substrate susceptor to the growing crystal. Therefore, forming the filling portion can suppress breakage and cracking. Furthermore, as a second effect, by forming a filling portion whose thermal expansion coefficient difference from the base portion is small, it can reduce stress concentration during cooling caused by the difference in thermal expansion coefficients. Thus, disposing a filling portion whose thermal expansion coefficient difference is small can further suppress breakage and cracking.

### Overview of Method for Producing Group-III Nitride Crystal

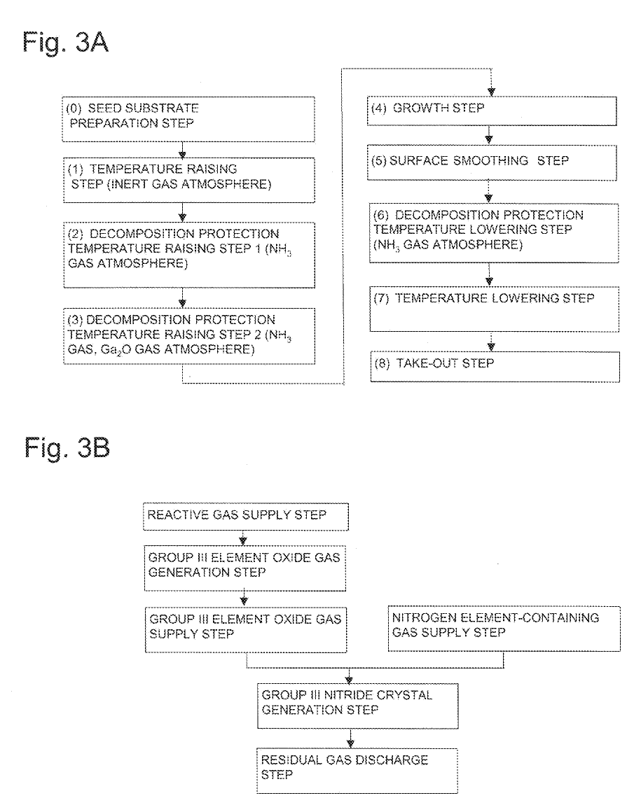

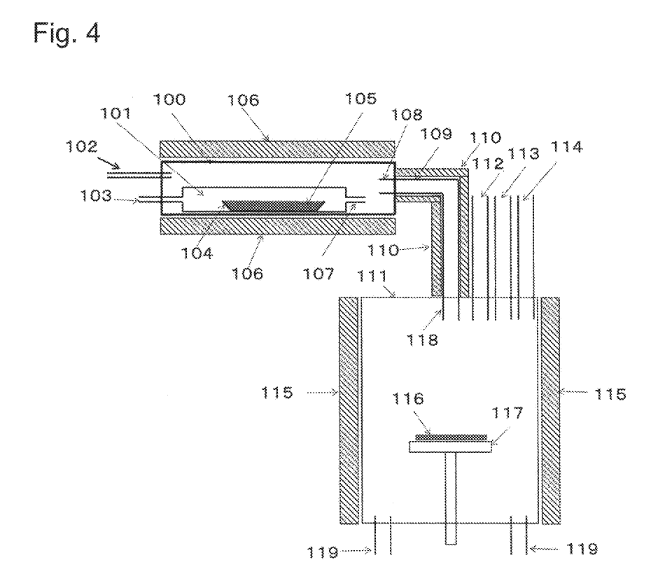

FIG. 3A is a chronological flowchart of the method for producing a Group-III nitride crystal according to the first embodiment, and FIG. 3B shows, as steps, the functional units from upstream to downstream within the production apparatus used in this production method. FIG. 4 is a schematic cross-sectional view of an apparatus for producing the Group-III nitride crystal according to the first embodiment.

An overview of the method for producing a Group-III nitride crystal according to the first embodiment will be described with reference to the flowchart of FIGS. 3A and 3B, and 4. The method for producing a Group-III nitride crystal comprises the steps of preparing a seed substrate, supplying a Group III element oxide gas and a nitrogen-containing gas to grow a Group-III nitride crystal on the seed substrate, and filling growth pits and smoothing the surface in the later stage of the step of growing the Group-III nitride crystal.

In the seed substrate preparation step of preparing a seed substrate 116, the seed substrate 116 is placed on a substrate susceptor 117.

In this embodiment, the method for producing a Group-III nitride crystal includes a temperature-raising step in which the temperature of a growth chamber 111 is raised to 100 °C or higher and lower than 500 °C in an inert gas atmosphere.

In this embodiment, the method for producing a Group-III nitride crystal includes a decomposition protection temperature-raising step 1. In the decomposition protection temperature-raising step 1, the temperature of the growth chamber 111 is raised to 500 °C or higher and lower than 1100 °C in an NH₃ gas atmosphere.

In this embodiment, the method for producing a Group-III nitride crystal includes a decomposition protection temperature-raising step 2. In the decomposition protection temperature-raising step 2, the temperature of the growth chamber 111 is raised to 1100 °C or higher and lower than 1500 °C in an atmosphere of NH₃ gas and Ga₂O gas.

In the growth step of growing a Group-III nitride crystal on the seed substrate 116, a Group III element oxide gas is generated in a source chamber 100 and supplied to the growth chamber 111, and a nitrogen-containing gas is also supplied to the growth chamber 111, thereby growing a Group-III nitride crystal on the seed substrate 116.

The growth step further comprises a reactive gas supply step, a Group III element oxide gas generation step, a Group III element oxide gas supply step, a nitrogen-containing gas supply step, a Group-III nitride crystal generation step, and a residual gas exhaust step. Note that each step included in the growth step may be carried out simultaneously within the apparatus for producing the Group-III nitride crystal.

In the reactive gas supply step, a reactive gas is supplied to a source reaction chamber 101.

In the Group III element oxide gas generation step, a starting Group III element source is reacted with a reactive gas (a reducing gas if the starting Group III

element source is an oxide, and an oxidizing gas if the starting Group III element source is a metal) to generate a Group III element oxide gas.

In the Group III element oxide gas supply step, the Group III element oxide gas generated in the Group III element oxide gas generation step is supplied to the growth chamber 111.

In the nitrogen-containing gas supply step, a nitrogen-containing gas is supplied to the growth chamber 111.

In the Group-III nitride crystal production step, the Group III element oxide gas supplied into the growth chamber 111 in the Group III element oxide gas supply step is reacted with and the nitrogen-containing gas supplied into the growth chamber 111 in the nitrogen-containing gas supply step, to grow a Group-III nitride crystal on the seed substrate.

In the residual gas exhaust step, unreacted gases not contributing to the formation of Group-III nitride crystals are exhausted to the outside of the chamber.

In this embodiment, the method for producing a Group-III nitride crystal includes a surface smoothing step. The surface smoothing step promotes two-dimensional growth of the Group-III nitride crystal (in the case of growth on the +c plane, growth that exposes the +c plane) and reduces surface irregularities in order to smooth the surface of the Group-III nitride crystal grown on the seed substrate 116.

In this embodiment, the method for producing a Group-III nitride crystal includes a decomposition protection temperature-reduction step. In the temperature-reduction step, the temperatures of the source chamber 100 and the growth chamber 111 are reduced to 500 °C while supplying NH₃ gas in order to suppress decomposition of the Group-III nitride crystal grown on the seed substrate 116.

In this embodiment, the method for producing a Group-III nitride crystal includes a temperature-reduction step. In the temperature-reduction step, the temperatures of the source chamber 100 and the growth chamber 111 are reduced to below 100 °C in an inert gas atmosphere.

In this embodiment, the method for producing a Group-III nitride crystal includes an unloading step. In the unloading step, the seed substrate 116 having a Group- III nitride crystal grown thereon is unloaded from the growth chamber 111.

### Overview of Apparatus For Producing Group-III Nitride Crystal

An overview of the apparatus used in the method for producing a Group-III nitride crystal according to the first embodiment will be described with reference to FIG. 4.

In FIG. 4, the size, ratio, etc. of each component may differ from the actual ones. The apparatus for producing the Group-III nitride crystal has the source reaction chamber 101 disposed within the source chamber 100, and a source boat 104 carrying a starting Group III element source 105 disposed within the source reaction chamber 101. A reactive gas supply pipe 103 is connected to the source reaction chamber 101, which supplies a gas that reacts with the starting Group III element source 105. The source reaction chamber 101 has a Group III element oxide gas exhaust port 107, which discharges the generated Group III element oxide gas. When the starting Group III source is an oxide, a reducing gas is used as the reactive gas. When the starting Group III source is a metal, an oxidizing gas is used as the reactive gas. A first carrier gas supply port 102 for supplying a first carrier gas is connected to the source chamber 100, and the first carrier gas supplied from the first carrier gas supply port 102 and the Group III element oxide gas discharged from the Group III element oxide gas exhaust port 107 flow from a gas exhaust port 108 through a connection pipe 109 to the growth chamber 111, and are supplied into the growth chamber 111 from a gas supply port 118 connected to the growth chamber 111. The growth chamber 111 has the gas supply port 118, a third carrier gas supply port 112, a nitrogen-containing gas supply port 113, a second carrier gas supply port 114, and an exhaust port 119. The growth chamber 111 has the substrate susceptor 117 on which the seed substrate 116 is placed.

### Details of Method and Apparatus For Producing Group-III Nitride Crystal

The method for producing a Group-III nitride crystal according to the first embodiment will be described in detail with reference to FIGS. 3 and 4.

In this embodiment, metallic Ga is used as the starting Group III element source 105, but the present invention is not limited thereto and, for example, Al or In may also be used.

First, the seed substrate 116 is prepared. For example, gallium nitride, gallium arsenide, silicon, sapphire, silicon carbide, zinc oxide, gallium oxide, or ScAlMgO₄ can be used as the seed substrate 116. In this embodiment, gallium nitride is used as the seed substrate 116.

In the temperature-increase step, the temperature of the growth chamber 111 is increased in an inert gas atmosphere to a temperature that does not cause decomposition of the seed substrate 116. In producing a Group-III nitride crystal by the OVPE method, heating is performed in an inert gas (e.g., N₂ gas) atmosphere up to approx. 500 °C.

In the decomposition protection temperature-increase step1, the temperature is increased in a nitrogen-containing gas atmosphere while suppressing decomposition of the seed substrate 116. In the production of Group-III nitride crystal by the OVPE method, heating is performed up to a temperature of 500 °C or higher but lower than 1100 °C in a state where an inert gas, a nitrogen-containing gas, and NH₃ gas are mixed. The reason for mixing NH₃ is to prevent decomposition of the seed substrate 116 due to the detachment of N atoms. Heating may also be performed in a state where H₂ gasis further mixed in.

In the decomposition protection temperature-increase step2, the temperature is increased in an atmosphere of Group III oxide gas and nitrogen-containing gas while suppressing decomposition of the seed substrate 116. In the production of Group-III nitride crystal by OVPE, heating is performed up to a temperature of 1100 °C or higher but lower than 1500 °C in a state where H₂ gas, an inert gas, Group III element oxide gas, and nitrogen-containing gas NH₃ gas are mixed. The reason for mixing the Group III element oxide gas is that decomposition cannot be suppressed with the nitrogen-containing gas alone. By applying a driving force for the growth of the Group-III nitride crystal, it becomes possible to suppress decomposition.

In the growth step, a Group III element oxide gas is generated in the source chamber 100 and supplied to the growth chamber 111, and a nitrogen-containing gas is also supplied to the growth chamber 111, to grow a Group-III nitride crystal three-dimensionally on the seed substrate 116. Specifically, the growth step includes a reactive gas supply step, a Group III element oxide gas generation step, a Group III element oxide gas supply step, a nitrogen-containing gas supply step, a Group-III nitride crystal production step, and a residual gas exhaust step.

In the reactive gas supply step, a reactive gas is supplied from the reactive gas supply pipe 103 to the source reaction chamber 101 in the source chamber 100. As described above, the reactive gas may be a reducing gas or an oxidizing gas as needed. In this embodiment, since metal Ga is used as the starting Group III element source 105, H₂O gas is used as the reactive gas.

In the Group III element oxide gas generation step, the reactive gas supplied to the source reaction chamber 101 in the reactive gas supply step reacts with Ga, which is the starting Group III element source 105, to generate Ga₂O gas, which is a Group III element oxide gas. The generated Ga₂O gas is discharged from the source reaction chamber 101 to the source chamber 100 via the Group III element oxide gas exhaust port 107. The discharged Ga₂O gas is mixed with a first carrier gas supplied to the source chamber 100 from the first carrier gas supply port 102, and supplied to the gas exhaust port 108. In this embodiment, the source chamber 100 is heated by a first heater 106. When the source chamber 100 is heated, the temperature of the source chamber 100 is preferably 800 °C or higher in view of the boiling point of Ga₂O gas. Furthermore, the temperature of the source chamber 100 is preferably set lower than that of the growth chamber 111. When the growth chamber 111 is heated by a second heater 115 as described below, the temperature of the source chamber 100 is preferably set to, for example, less than 1800 °C. The starting Group III element source 105 is placed in the source boat 104 disposed in the source reaction chamber 101. The source boat 104 preferably has a shape that can increase the contact area between the reactive gas and the starting Group III element source 105. For example, the source boat 104 preferably has a multi-tiered dish shape to prevent the starting Group III element source 105 and the reactive gas from passing through the source reaction chamber 101 without coming into contact with each other.

Methods for generating a Group III element oxide gas can be broadly divided into methods for reducing the starting Group III element source 105 and methods for oxidizing the starting Group III element source 105. For example, the reduction method uses an oxide (e.g., Ga ₂O₃) as the starting Group III element source 105 and a reducing gas (e.g., H₂ gas, CO gas, CH₄ gas, C₂H₆ gas, H₂S gas, or SO₂ gas) as the reactive gas. On the other hand, the oxidation method uses a non-oxide (e.g., liquid Ga) as the starting Group III element source 105 and an oxidizing gas (e.g., H₂O gas, O₂ gas, CO gas, CO₂ gas, NO gas, N₂O gas, or NO₂ gas) as the reactive gas. In addition to the starting Group III element source 105, an In source or an Al source can also be used as the starting Group III element. An inert gas, H₂ gas, or the like can be used as the first carrier gas.

In the Group III element oxide gas supply step, Ga₂O gas generated in the Group III element oxide gas generation step is supplied to the growth chamber 111 via the gas exhaust port 108, the connection pipe 109, and the gas supply port 118. When the temperature of the connection pipe 109 connecting the source chamber 100 and the growth chamber 111 drops below the temperature of the source chamber 100, a reverse reaction of the reaction for generating the Group III element oxide gas occurs, and a starting Ga source 105 precipitates inside the connection pipe 109. Therefore, it is preferable that the connection pipe 109 be heated by a third heater 110 to a temperature higher than that of the first heater 106 so that the temperature does not drop below that of the source chamber 100.

In the nitrogen-containing gas supply step, a nitrogen-containing gas is supplied to the growth chamber 111 from the nitrogen-containing gas supply port 113. Examples of the nitrogen-containing gas include NH₃ gas, NOgas, NO₂ gas, N₂O gas, N₂H₂ gas, and N₂H₄ gas.

In the Group-III nitride crystal growth process, the source gases supplied into the growth chamber 111 through each supply process are reacted to grow a Group-III nitride crystal on the seed substrate 116. The growth chamber 111 is preferably heated by the second heater 115 to a temperature at which the Group III element oxide gas and the nitrogen-containing gas react. At this time, the temperature of the growth chamber 111 is preferably controlled so that it does not drop below the temperature of the source chamber 100, in order to prevent a reverse reaction of the reaction that produces the Group III element oxide gas. The temperature of the growth chamber 111 heated by the second heater 115 is preferably 1000 °C or higher and 1800 °C or lower. Furthermore, in order to suppress temperature fluctuations in the growth chamber 111 due to the Ga ₂O gas generated in the source chamber 100 and the first carrier gas, it is desirable that the temperatures of the second heater 115 and the third heater 111 be the same.

By mixing the Group III element oxide gas supplied to the growth chamber 111 via the Group III element oxide gas supply step and the nitrogen-containing gas supplied to the growth chamber 111 via the nitrogen-containing gas supply step upstream of the seed substrate 116, it is possible to grow a Group-III nitride crystal on the seed substrate 116.

The reactive gas supply step, the Group III element oxide gas generation step, the Group III element oxide gas supply step, the nitrogen-containing gas supply step, the Group-III nitride crystal production step, and the residual gas exhausting step, which are included in the growth step, may be performed simultaneously.

The second carrier gas used may be an inert gas, H₂ gas, or the like.

In the residual gas exhaust process, the unreacted Group III element oxide gas and nitrogen-containing gas, as well as the first carrier gas, second carrier gas, and third carrier gas, are exhausted from the exhaust port 119.

Furthermore, from the perspective of increasing the carrier concentration, the base portion of the Group-III nitride crystal formed by the growth step preferably has an oxygen density of 1×10²⁰ atoms/cm³ or more, and more preferably has an oxygen density of 1×10²¹ atoms/cm³ or more.

Furthermore, growth pits generated during the growth process have the effect of coalescing and eliminating dislocations in the seed substrate. Therefore, from the viewpoint of improving the quality of the base portion, the density of growth pits is preferably 5×10⁵ cm⁻² or less, and more preferably 1×10⁵ cm⁻² or less.

In the course of the smoothing the growth surface, two-dimensional growth of the Group-III nitride crystal is promoted rather than three-dimensional growth toward the end of the growth process in order to smooth out irregularities such as growth pits that occurred during the growth process. By promoting two-dimensional growth, irregularities such as growth pits are filled in, forming a filling portion, and the surface is smoothed. There are two main methods for promoting two-dimensional growth. One is to increase the growth temperature. The other is to increase the V/III ratio (the ratio of Group V source to Group III source). By implementing either or both of these methods, the surface irregularities can be filled in. Specifically, it is desirable to increase the V/III ratio by five times or more. Furthermore, it is desirable to perform the growth at a temperature of the seed substrate that is 50 °C or higher than that of the growth process described above. These conditions may be used selectively, or may be used in combination.

In the decomposition protection temperature-reduction step, the temperature is reduced in a nitrogen-containing gas atmosphere while suppressing decomposition of the Group-III nitride crystal. In the production of Group-III nitride crystal by the OVPE method, the cooling is performed to 500 °C or below in a state in which an inert gas and a nitrogen-containing gas (NH₃ gas) are mixed.

In the temperature-reduction step, the temperature is reduced in an inert gas atmosphere to a temperature at which the Group-III nitride crystal can be removed from the growth chamber 111.

In this embodiment, the seed substrate 116 having the Group-III nitride crystal grown thereon is removed from growth chamber 111 after the temperature-reduction step.

### Relationship between Oxygen Density in Filling Portion and Stress in Filling Portion

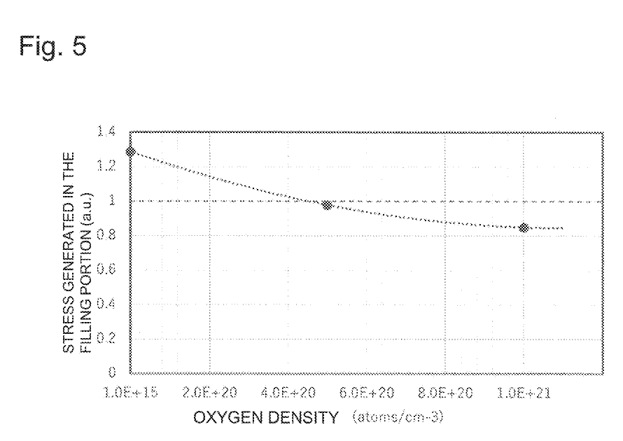

FIG. 5 shows the relationship between the oxygen density of the filling portion and the stress caused by the difference in thermal expansion coefficients in the region (filling portion) where the growth pits are filled. The results in FIG. 5 are analytical values from a thermal stress analysis when the oxygen density of the base portion is 1×10²¹ atoms/cm³. The dotted line in FIG. 5 represents the stress in the growth pit when the surface smoothing process is not performed. As can be seen from this, when the oxygen density of the filling portion exceeds 4.8×10²⁰ atoms/cm³, the stress generated in the filling portion can be reduced compared to when the filling portion is not formed. From this, from the viewpoint of suppressing the stress caused by the difference in thermal expansion coefficients, it is preferable to set the oxygen density of the filling portion to 4.8 ×10²⁰ atoms/cm³ or more. Furthermore, the implementation of the filling portion suppresses cracking and breakage. Hence, it can be seen that simply forming the filling portion suppresses the load on the grown crystal and is effective in reducing cracking and breakage. The reason for this is that the substrate (growing crystal) is rotated during growth and cooling to equalize the gas partial pressure on the growing crystal surface. As the growing crystal rotates, it may come into contact with the substrate susceptor. This contact places a load on the growing crystal, which is more likely to cause breakage or cracks when no filling portion is formed.

According to the Group-III nitride crystal according to the present disclosure, the production yield during the production of Group-III nitride crystal can be improved, and high-quality Group-III nitride crystal can be produced.

### REFERENCE SIGNS LIST

100 Source chamber
101 Source reaction chamber
102 First carrier gas supply port
103 Reactive gas supply pipe
104 Source boat
105 Starting Group III element source
106 First heater
107 Group III element oxide gas exhaust port
108 Gas exhaust port
109 Connection pipe
110 Third heater
111 Growth chamber
112 Third carrier gas supply port
113 Nitrogen-containing gas supply port
114 Second carrier gas supply port
115 Second heater
116 Seed substrate
117 Substrate susceptor
118 Gas supply port
119 Exhaust port

What is claimed is:

1. A Group-III nitride crystal, comprising:
a base portion made of Group-III nitride crystal, having a growth surface with a recessed growth pit; and
a filling portion made of Group-III nitride crystal filling in the recessed growth pit on the growth surface.

2. The Group-III nitride crystal according to claim 1, wherein the growth pit is filled with a Group-III nitride crystal, and
the base portion has an oxygen density of 1×10²⁰ atoms/cm³ or more.

3. The Group-III nitride crystal according to claim 1,
wherein the growth pit is filled with a Group-III nitride crystal,
the base portion has an oxygen density of 1×10²¹ atoms/cm³ or more, and
the filling portion has an oxygen density of 4.8×10²⁰ atoms/cm³ or more.

4. The Group-III nitride crystal according to claim 1,
wherein the growth pit is filled with a Group-III nitride crystal, and
the dislocation density is 5×10⁵cm⁻² 4or less.

5. A method for producing a Group-III nitride crystal, comprising:
preparing a seed substrate;
growing a Group-III nitride crystal three-dimensionally on the seed substrate by supplying a Group III element oxide gas and a nitrogen-containing gas onto the seed substrate so as to form a base portion made of the Group-III nitride crystal on the seed substrate, the base portion having a growth surface with a recessed growth pit; and
smoothing the growth surface of the base portion made of the Group-III nitride crystal by two-dimensionally growing a Group-III nitride crystal as a filling portion to fill in the recessed growth pits on the growth surface.

6. The method for producing a Group-III nitride crystal according to claim 5, wherein smoothing the growth surface includes controlling the amounts of the Group III element oxide gas and the nitrogen-containing gas to be supplied to set the V/III ratio to 5 or greater.

7. The method for producing a Group-III nitride crystal according to claim 5, wherein smoothing the growth surface includes increasing the temperature of the seed substrate by 50°C or more from that in the step of growing the Group-III nitride crystal.

8. The method for producing a Group-III nitride crystal according to claim 5, wherein in the course of smoothing the growth surface of the Group-III nitride crystal, the oxygen density in a region where the recessed growth pits have been filled in is 4.8×10²⁰ atoms/cm³ or more.
